(19) United States
(12) Patent Application Publication
(10) Pub. No.: US 2026/0371788 A1
(43) Pub. Date: Nov. 19, 2026

(54) LIGHT-EMITTING ELEMENT AND LIGHT-EMITTING DEVICE

(71) Applicant: Xiamen San'an Optoelectronics Co., Ltd., Fujian (CN)

(72) Inventors: Yung-ling LAN, Fujian (CN); Jiali ZHUO, Fujian (CN); Chi-ming TSAI, Fujian (CN); Chung-Ying CHANG, Fujian (CN); Zhiming LI, Fujian (CN)

(73) Assignee: Xiamen San'an Optoelectronics Co., Ltd., Fujian (CN)

(21) Appl. No.: 18/613,131

(22) Filed: Mar. 22, 2024

(30) Foreign Application Priority Data
Mar. 27, 2023 (CN) 202310307788.X

(51) Int. Cl. H10H 20/812; H10H 20/816

(52) U.S. Cl. CPC H10H 20/812; H10H 20/8162

(57) ABSTRACT

A light-emitting element and a light-emitting device are provided. A semiconductor structure of a light-emitting element at least includes a first semiconductor layer, a superlattice structure layer, an active layer, and a second semiconductor layer stacked from bottom to top. The active layer is a multiple quantum well structure, and the second semiconductor layer is a P-type doped layer. A P-type dopant diffuses into the active layer and the superlattice structure layer, the P-type dopant forms a sudden drop region and a slow drop region in the active layer, and in the active layer and the superlattice structure layer, a diffusion depth of the P-type dopant is not greater than 500 nm. The maximum value of diffusion concentration of Mg atoms appears in a range of 20 nm to 35 nm from the surface of the active layer.

### CROSS-REFERENCE TO RELATED APPLICATION

This application claims the priority benefit of China application serial no. 202310307788.X, filed on Mar. 27, 2023. The entirety of the above-mentioned patent application is hereby incorporated by reference herein and made a part of this specification.

### BACKGROUND

### Technical Field

The disclosure relates to the technical field of semiconductor component and device, and in particular to a light-emitting element and a light-emitting device.

### Description of Related Art

Due to the high luminous efficiency, GaN-based LEDs have been widely used in various light source fields such as backlighting, lighting, car lights, and decoration. From a technical perspective, further improving the luminous efficiency of LED chips is still the focus of current industry development. The luminous efficiency is mainly determined by two factors, the first is the efficiency of electron-hole radiative recombination in the active region, that is, the internal quantum efficiency, and the second is the light extraction efficiency.

For nitride light-emitting diodes, in order to improve the luminous efficiency, various semiconductor structures are usually used to improve the internal quantum efficiency. One of the factors that affects the internal quantum efficiency is that magnesium (Mg) atoms diffuse into multiple quantum wells (MQW) and affect the quality of the MQW, resulting in a reduction in the luminous efficiency of the active layer, in which Mg atoms diffuse through planes and material defects V-pit portion. In the existing technology, although the electron overflow can be reduced by improving the epitaxial layer structure, the higher the current density, the lower the blocking effect on electrons, which in turn affects the efficiency of electron-hole recombination. In order to effectively improve the internal quantum efficiency of the epitaxial layer and achieve high luminous efficiency of the light-emitting diode, it is necessary to provide a solution that can effectively control and regulate the diffusion of Mg atoms.

### SUMMARY

In view of the above-mentioned defects of nitride light-emitting diodes in the related art, the disclosure provides a light-emitting element and a light-emitting device to solve one or more of the above problems.

The first aspect of the disclosure provides a light-emitting element that includes a semiconductor structure, the semiconductor structure includes a first semiconductor layer, a superlattice structure layer, an active layer, and a second semiconductor layer, the active layer is a multiple quantum well structure, the second semiconductor layer is a P-type doped layer and has a P-type dopant, wherein the P-type dopant diffuses to the active layer from the second semiconductor layer and forms a sudden drop region and a slow drop region, and a depth of the P-type dopant diffused from the active layer is not greater than 500 nm.

Optionally, in the active layer, a concentration of the P-type dopant is in a range of 1×10¹⁷atom/cm³ to 5×10¹⁹ atom/cm³.

Optionally, the semiconductor structure further includes an electron blocking layer formed between the active layer and the second semiconductor layer, and the P-type dopant has a peak concentration in the electron blocking layer.

Optionally, in the sudden drop region, a diffusion depth of the P-type dopant does not exceed two quantum wells, and a concentration of the P-type dopant is in a range of 1×10¹⁸ atom/cm³ to 5×10²⁰ atom/cm³.

Optionally, the sudden drop region has a first sudden drop region and a second sudden drop region, the first sudden drop region is formed in the electron blocking layer, the second sudden drop region is formed in the active layer, in the first sudden drop region, a concentration of the P-type dopant is in a range of 1×10¹⁹ atom/cm³ to 5×10²⁰ atom/cm³, and in the second sudden drop region, a concentration of the P-type dopant is in a range of 1×10¹⁸ atom/cm³ to 2×10¹⁹ atom/cm³.

Optionally, in the active layer, a quantity of pairs of quantum well and barrier layer is 3 to 15 pairs, and a quantity of pairs of material layer whose concentration of the P-type dopant being greater than 2×10¹⁸ atom/cm³ is less than or equal to 2.

Optionally, the slow drop region is formed subsequent to the sudden drop region in the active layer, and in the slow drop region, a concentration of the P-type dopant is in a range of 1×10¹⁷ atom/cm³ to 2×10¹⁸ atom/cm³.

Optionally, the sudden drop region has a first sudden drop region, a buffer region, and a second sudden drop region, the first sudden drop region, the buffer region, and the second sudden drop region are formed in the active layer.

Optionally, in the first sudden drop region, a concentration of the P-type dopant is in a range of 2×10¹⁹ atom/cm³ to 5×10²⁰ atom/cm³, in the buffer region, a concentration of the P-type dopant is in a range of 1×10¹⁹ atom/cm³ to 2×10¹⁹ atom/cm³, and in the second sudden drop region, a concentration of the P-type dopant is in a range of 1×10¹⁸ atom/cm³ to 2×10¹⁹ atom/cm³.

Optionally, in the second sudden drop region, a diffusion depth of the P-type dopant does not exceed two quantum wells.

Optionally, in a stacking direction of the semiconductor structure, a first pair of quantum well and barrier layer of the active layer are adjacent to the first semiconductor layer, a last pair of barrier layer and quantum well of the active layer are adjacent to the second semiconductor layer, and in the quantum well of the first pair, a concentration of the P-type dopant is greater than 5×10¹⁶ atom/cm³ and less than 1×10¹⁷ atom/cm³.

Optionally, in the quantum well of the last pair, a concentration of the P-type dopant is greater than 1×10¹⁸ atom/cm³ and less than 1×10¹⁹ atom/cm³.

Optionally, a second-to-last pair of quantum well and barrier layer of the active layer is adjacent to the last pair of quantum well and barrier layer, and in the quantum well of the second-to-last pair, a concentration of the P-type dopant is greater than 1×10¹⁸ atom/cm³ and less than 2×10¹⁸ atom/cm³.

Optionally, the quantum well in the active layer is an indium-containing layer.

Optionally, in the superlattice structure layer, a concentration of the P-type dopant is less than 5×10¹⁶ atom/cm³.

Optionally, the P-type dopant is a magnesium atom.

According to another embodiment of the disclosure, a light-emitting device is provided, which includes the light-emitting element of the disclosure.

As mentioned above, the light-emitting element and the light-emitting device according to the disclosure have beneficial effects as follows.

In the light-emitting element according to the disclosure, the P-type dopant in the second semiconductor layer diffuses to the active layer from the second semiconductor layer and forms a sudden drop region and a slow drop region, and a depth of the P-type dopant diffused from the active layer is not greater than 500 nm. In the sudden drop region, the diffusion depth of the P-type dopant does not exceed two quantum wells, and the concentration of the P-type dopant is in a range of 1×10¹⁸ atom/cm³ to 5×10²⁰ atom/cm³. In the active layer, the concentration of the P-type dopant is in a range of 1×10¹⁷atom/cm³ to 5×10¹⁹ atom/cm³. By controlling the diffusion depth of Mg atoms in the sudden drop region and the concentration range of Mg atoms in the sudden drop region, the efficiency of electron-hole recombination in the active layer can be improved, the internal quantum efficiency of the epitaxial layer can be improved, and the high luminous efficiency of the light-emitting diode can be achieved.

Subsequent to the sudden drop region, Mg atoms form a slow drop region. The concentration of Mg atoms in the slow drop region is in a range of 1×10¹⁷ atom/cm³ to 2×10¹⁸ atom/cm³. As mentioned above, by controlling the depth of Mg atoms in the slow drop region and the concentration change of Mg in the slow drop region, the concentration of the P-type dopant in a first superlattice layer is 5×10¹⁶ atom/cm³, thereby the non-luminous electron-hole recombination in a non-active region (such as a stress buffer layer, that is, the superlattice layer) can be reduced as much as possible, and the luminous electron-hole recombination in the active area can be increased.

In addition, the P-type doped sudden drop region may further be divided into the first sudden drop region, the buffer region, and the second sudden drop region. The buffer region is beneficial to well controlling the concentration of the P-type dopant in MQW to be in a range of 1×10¹⁷ atom/cm³ to 5×10¹⁹ atom/cm³. The impact of Mg atoms on the MQW is effectively reduced, the quality of MQW is improved, thereby the efficiency of electron-hole recombination in the active layer is improved, the internal quantum efficiency of the epitaxial layer is improved, and high luminous efficiency of the light-emitting diode is achieved.

### BRIEF DESCRIPTION OF THE DRAWINGS

FIG. 1 shows a schematic structural diagram of a light-emitting element according to Embodiment 1 of the disclosure.

FIG. 2 shows a schematic diagram of concentration peak shapes of Mg (magnesium) and In (indium) elements in an semiconductor structure shown in FIG. 1.

FIG. 3 shows a partially enlarged schematic diagram of a part A in FIG. 1.

FIG. 4 shows a schematic diagram of a concentration peak shape of each element in the semiconductor structure of the light-emitting element according to Embodiment 2 of the disclosure, in which merely diagrams of the concentration peak shapes of Mg atoms and In atoms in the active layer is shown.

FIG. 5 shows a schematic diagram of a concentration peak shape of each element in the semiconductor structure of the light-emitting element according to Embodiment 3 of the disclosure, in which merely diagrams of the concentration peak shapes of Mg atoms and In atoms in the active layer is shown.

FIG. 6 shows a schematic structural diagram of a light-emitting device according to Embodiment 4 of the disclosure.

### DESCRIPTION OF THE EMBODIMENTS

The following describes the embodiments of the disclosure through specific examples. Persons skilled in the art may easily understand other advantages and effects of the disclosure from the content disclosed in the specification. The disclosure may also be implemented or applied through other different specific embodiments. Various details in the specification may also be modified or changed in various ways based on different viewpoints and applications without departing from the spirit of the disclosure.

The composition of each layer included in the disclosure may be analyzed by any suitable method, such as secondary ion mass spectrometry (SIMS). The thickness of each layer may be analyzed by any suitable method, such as transmission electron microscopy (TEM) or scanning electron microscopy (SEM) in conjunction with, for example, the depth position of each layer on a SIMS map.

### Embodiment 1

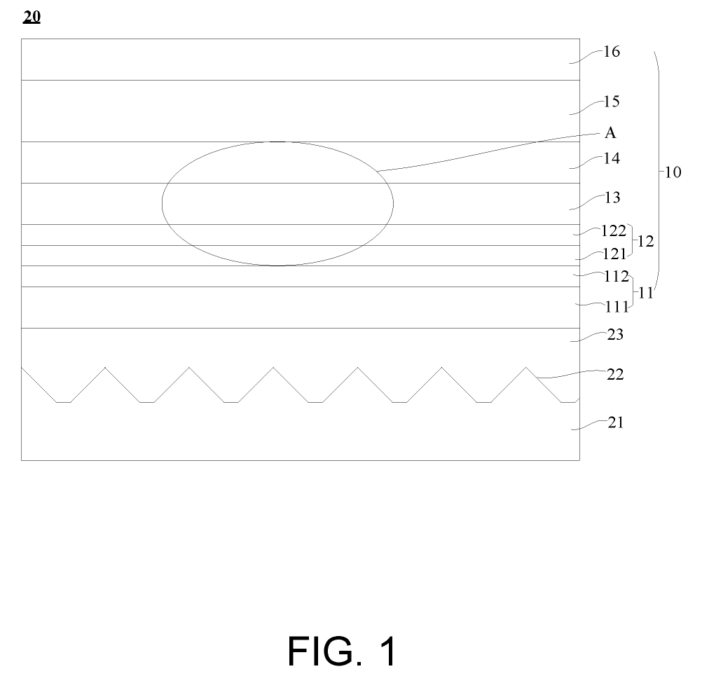

The embodiment provides a light-emitting element (also called LED, referred to as light-emitting diode in the subsequent description). As shown in FIG. 1, a light-emitting diode 20 at least includes an semiconductor structure 10, and the semiconductor structure 10 at least includes a first semiconductor layer 11, a superlattice structure layer 12, an active layer 13, and a second semiconductor layer 15 sequentially stacked from bottom to top. The semiconductor structure 10 may be any semiconductor structure that can radiate light under the action of voltage, for example, an AlGaInN-based semiconductor structure or an AlGaInP-based semiconductor structure. In this embodiment, the description takes the semiconductor structure 10 being an AlGaInN-based semiconductor structure which can provide blue light or green light as an example.

The first semiconductor layer 11 may be an N-type layer, correspondingly, the second semiconductor layer 15 may be a P-type layer, and vice versa. In this embodiment, the description takes the first semiconductor layer 11 being an N-type layer, and correspondingly, the second semiconductor layer 15 being a P-type layer as an example. As shown in FIG. 1, the first semiconductor layer 11 may include an N-type electron injection layer 111 and an N-type current expansion layer 112.

In this embodiment, the N-type electron injection layer 111 is an N-type GaN layer configured to to provide electrons. The N-type electron injection layer 111 provides the electrons by doping n-type impurities, and the n-type impurities may be, for example, Si, Ge, Sn, Se, and Te. In this embodiment, the n-type impurity is preferably Si. The thickness of the N-type electron injection layer 111 is approximately 1 μm to 4 μm, and the Si doping concentration is in a range of 1×10¹⁹Atoms/cm³ to 1×10²⁰Atoms/cm³ to provide electrons for radiative recombination. The N-type electron injection layer 111 is the layer with the highest n-type doping concentration in the semiconductor structure 10. The N-type electron injection layer 111 may be a single layer structure or a superlattice structure (such as repeated stacking layers of two GaN layers with high and low doping concentrations). The N-type electron injection layer 111 is formed as a highly doped layer, which can reduce contact resistance.

The N-type current expansion layer 112 is grown on the N-type electron injection layer 111, which can increase the lateral expansion of current. The current expansion layer 112 is a low N-type doping layer, the Si doping concentration of the current expansion layer 112 is in a range of 1×10¹⁷Atoms/cm³ to 2×10¹⁸ Atoms/cm³, and the Si doping concentration of the current expansion layer 112 is less than the Si doping concentration of the N-type electron injection layer 111. The current expansion layer 112 can increase the lateral expansion of current. The thickness of the current expansion layer 112 is less than or equal to 0.3 μm, preferably 0.01 μm or more. Excessive thickness causes the voltage to increase. The growth temperature of the N-type electron injection layer 111 and the current expansion layer 112 is 1000° C or more.

As shown in FIG. 1, the active layer 13 is formed on the superlattice structure layer 12. The active layer 13 provides a region where electrons and holes recombine to generate light radiation. Depending on the wavelength of light, different materials may be selected. The active layer 13 may be a single quantum well or a multi-quantum well periodic structure comprising a quantum well 131 and a barrier layer 132. By adjusting the composition ratio of the semiconductor material in the active layer 13, it is expected to radiate light of different wavelengths. In some embodiments, the active layer 13 has InGaN/GaN multi-quantum well of 5 to 15 cycles, or the active layer 13 has InGaN/AlGaN multi-quantum well of 5 to 15 cycles. Also, the starting layer of the active layer 13 is the quantum well 131, and the ending layer is the barrier layer 132. In the active layer 13, the Si doping concentration of the barrier layer 132 is in a range of 1×10¹⁷atom/cm³ to 1×10¹⁸atom/cm³. The thickness of InGaN in each cycle is 1nm to 4 nm, and the thickness of GaN is 3 nm to 20 nm. In some embodiments, the barrier layer 132 of the quantum well may be doped with a small amount of Al, consisting of AlGaN.

In this embodiment, as shown in FIG. 3, preferably, the active layer 13 is a multi-quantum well periodic structure comprising Inₓ₂Ga₍₁₋ₓ₂₎N quantum well 131 and Al_{y2}Ga_{(1-y2)}N barrier layer 132, in which 0.08≤x2≤0.18 and 0.02≤y2≤0.08. The barrier layer 132 has a larger band gap than the quantum well 131. Also shown in FIG. 3, V-surface pits are constructed reasonably to improve the efficiency of hole injection, and thus in the light-emitting element in this embodiment, V-surface pits 130 are formed in the active layer 13. However, the V-surface pits 130 also form diffusion channels for the P-type dopant, affecting the diffusion depth of the P-type dopant, thereby affecting the internal quantum efficiency of the active layer 13.

As shown in FIG. 1, a second semiconductor layer 15 is formed above the active layer 13, and an electron blocking layer 14 is further formed between the active layer 13 and the second semiconductor layer 15. The second semiconductor layer 15 is a P-type GaN layer, which provides holes by doping P-type impurity. The P-type impurity may be Mg, Zn, Ca, Sr, and Ba. In this embodiment, preferably, the P-type impurity is Mg. An ohmic contact layer 16 is further formed above the second semiconductor layer 15. Through high doping concentration, for example, a doping concentration being higher than 1×10²⁰ Atoms/cm³, an ohmic contact is formed with the P-type electrode of the subsequently formed nitride light-emitting diode. The thickness of the second semiconductor layer 15 is 100nm or more, more preferably, 300nm or less, to ensure that the P-type GaN layer may fill the V-surface pits 130 and improve the micro-pit phenomenon of the semiconductor epitaxial stack layer, thereby improving the reliability of the nitride light-emitting diode.

As shown in FIG. 1, in an optional embodiment, the superlattice structure layer 12 includes a first superlattice layer 121 formed above the N-type current expansion layer 112 and a second superlattice layer 122 formed above the first superlattice layer 121. The first superlattice layer 121 and the second superlattice layer 122 are beneficial to further controlling the diffusion depth and diffusion concentration of the P-type dopant in the P-type layer, and are beneficial to improving the efficiency of electron-hole recombination in the active layer 13. The first superlattice layer 121 is located above the N-type current expansion layer 112, and the first superlattice layer 121 is formed between the current expansion layer 112 and the active layer 13, which can control/induce the opening of the V-surface pit 130 shown in FIG. 3, further playing the role of releasing the stress.

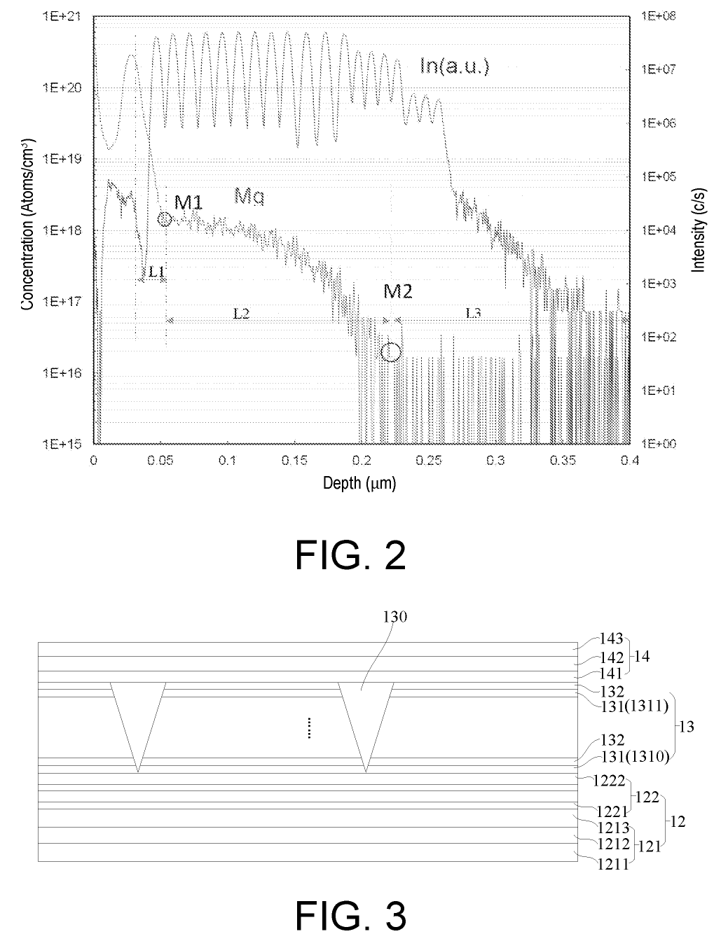

As shown in FIGS. 2 and 3, the P-type dopant Mg atoms diffuse into the active layer 13, the Mg atoms form a sudden drop region L1 and a slow drop region L2 during the diffusion process, and in the active layer 13, a diffusion depth of the Mg atoms is not greater than 500 nm. In the active layer 13, a concentration of Mg atoms is in a range of 1×10¹⁷atom/cm³ to 5×10¹⁹ atom/cm³, in which Mg atoms form a peak concentration prior to the active layer 13. The peak concentration appears in the electron blocking layer 14 between the active layer 13 and the second semiconductor layer 15, that is, the sudden drop region L1 is formed from the electron blocking layer 14 to the active layer 13. In the stacking direction of the semiconductor structure 10, the first pair of quantum well 131 and barrier layer 132 of the active layer 13 are defined adjacent to the first semiconductor layer 11, and the last pair of barrier layer 132 and quantum well 131 of the active layer 13 are defined adjacent to the second semiconductor layer 15. Therefore, the peak concentration of the concentration peak shape of Mg atoms also appears in the electron blocking layer 14 above a last layer of quantum well 1311 (the quantum well 1311 of the last pair) of the active layer 13. Also, in the electron blocking layer 14, a concentration of Mg atoms is in a range of 2×10¹⁹ atom/cm³ to 5×10²⁰ atom/cm³, in which the peak concentration of the concentration peak shape may be approximately 3×10²⁰ atom/cm³.

As shown in FIG. 2, in the sudden drop region L1, a concentration of Mg atoms is in a range of 1×10¹⁸ atom/cm³ to 5×10²⁰ atom/cm³, and the diffusion depth of the P-type dopant in the active layer 13 does not exceed two quantum wells. In the active layer 13, the quantity of pairs of quantum well 131 and barrier layer 132 whose concentration of Mg atom being greater than 2×10¹⁸ atom/cm³ is less than or equal to 2 pairs. For example, as shown in FIG. 3, optionally, at the last layer of quantum well 1311 (the quantum well 1311 of the last pair) of the active layer 13, the concentration of Mg atoms is less than 1×10¹⁹ atom/cm³, and at the second-to-last layer of quantum well 131 (the quantum well 1311 of the second-to-last pair), the concentration of Mg atoms is greater than 1×10¹⁸ atom/cm³, preferably less than or equal to 2×10¹⁸ atom/cm³. Also shown in FIG. 2, the slow drop region L2 is formed subsequent to the sudden drop region L1 in the active layer. In the slow drop region, the concentration of Mg atoms is in a range of 2×10¹⁶ atom/cm³ to 2×10¹⁸ atom/cm³. Also, in the remaining quantum well 131 and barrier layer 132 of the active layer 13, in the first quantum well adjacent to the first semiconductor layer 11, the concentration of Mg atoms is greater than 5×10¹⁶ atom/cm³ and less than 2×10¹⁷ atom/cm³. By controlling the depth of the sudden drop region of Mg atoms and the concentration change of Mg atoms in the sudden drop region, the efficiency of electron-hole recombination in the active layer can be improved, the internal quantum efficiency of the epitaxial layer can be improved, and the high luminous efficiency of the light-emitting diode can be achieved.

From the active layer 13 to the superlattice structure layer 12 adjacent to the active layer 13, the concentration of Mg atoms continues to drop, and the concentration in the superlattice structure layer 12 drops to less than 5×10¹⁶ atom/cm³. Referring to FIG. 2, the curve of the concentration of Mg atoms further includes an L3 section along the depth direction, the position M2 is between the slow drop region L2 and the L3 section, the L3 section represents the concentration of Mg atoms in the superlattice structure layer 12, the ups and downs appear in the L3 section are mainly noise signals for testing, the concentration of Mg atoms thereof is generally less than 1E16 (1×10¹⁶ atom/cm³), and the doping concentration of Mg atoms is negligible. The depth of the slow drop region of Mg atoms and the concentration change of Mg in the slow drop region are controlled so that the concentration of the P-type dopant in the first superlattice layer is less than 5×10¹⁶ atom/cm³, thereby the non-luminous electron-hole recombination in a non-active region (such as a stress buffer layer, that is, the superlattice layer) can be reduced as much as possible, and the luminous electron-hole recombination in the active area can be increased.

By controlling the diffusion depth and the concentration change in diffusion of Mg atoms, the impact of Mg atoms on the MQW can be effectively reduced, the quality of MQW can be improved, thereby the efficiency of electron-hole recombination in the active layer 13 is improved, the internal quantum efficiency of the epitaxial layer is improved, and the high luminous efficiency of the light-emitting diode is achieved.

As shown in FIG. 3, the V-surface pit 130 may be a pyramid, such as a pit formed in a hexagonal pyramid-shape. By controlling the thickness of the second semiconductor layer 15, that is, the P-type layer, it is beneficial to filling the V-surface pits 130, thereby reducing the path of the leakage channel, and the luminous efficiency of LED is improved.

In order to prevent electron overflow, the electron blocking layer 14 is further formed between the second semiconductor layer 15 and the active layer 13. The electron blocking layer 14 may be anAlₐIn_{b}Ga_{(1-a-b)}N layer, in which 0 <a≤1, 0≤b<1. As shown in FIG. 3, preferably, the AlₐIn_{b}Ga_{(1-a-b)}N layer includes a first sub-layer 141, a second sub-layer 142, and a third sub-layer 143 sequentially stacked from bottom to top. The In (indium) component content of the third sub-layer 143 is higher than the In component content of the first sub-layer 141 and the second sub-layer 142. The In content of the second sub-layer 142 may be less than the In content of the first sub-layer 141 and may also be higher than the In content of the first sub-layer 141. The Al (aluminum) content of the first sub-layer 141 is higher than the Al content of the second sub-layer 142, and the Al content of the third sub-layer 143 is higher than the Al content of the second sub-layer 142.

The first sub-layer 141 is disposed on the active layer 13. The first sub-layer 141 may function as the electron blocking layer 14. The first sub-layer 141 may comprise one or more materials such as AlN, AlGaN, or AlInGaN. The second sub-layer is arranged between the first sub-layer 141 and the third sub-layer 143, and the In component content thereof is less than the In component content of the first sub-layer 141 and the third sub-layer 143. The second sub-layer may comprise at least one of AlGaN, GaN, and AlInGaN. The second sub-layer is a hole injection layer, and the thickness of the second sub-layer is 3 nm to 70 nm. In some embodiments, the thickness of the second sub-layer is preferably 8 nm or more, more preferably, in a range of 10 nm to 50 nm. The P-type doping concentration of the second sub-layer is 1×10¹⁹ Atoms/cm³ or more, preferably 5×10¹⁹Atoms/cm³ or more, for example, 1×10²⁰ to 2×10²⁰Atoms/cm³. By increasing the P-type doping concentration of the second sub-layer, the hole injection efficiency can be improved. The third sub-layer 143 may comprise one or more materials such as AlN, AlGaN, and AlInGaN and may function as the electron blocking layer 14.

Also as shown in FIG. 1, the light-emitting diode 20 further includes a first electrode and a second electrode formed on the semiconductor structure. The first electrode is electrically connected to the first semiconductor layer 11, for example, electrically connected to the first semiconductor layer 11 through the electrical current expansion layer 112, and the second electrode is electrically connected to the second semiconductor layer 15, for example, electrically connected to the second semiconductor layer 15 through the ohmic contact layer 16.

Also as shown in FIG. 1, the light-emitting diode 20 may further include a substrate 21, and the substrate 21 is an insulating substrate or a conductive substrate. The substrate 21 is a growth substrate used for epitaxial growth of the semiconductor epitaxial stack layer, including sapphire (Al₂O₃). The substrate 21 includes a first surface and a second surface arranged opposite to each other. The upper surface of the substrate 21 may have a plurality of pattern structures 22, and the pattern structures 22 may be formed into regular and/or irregular patterns. In this embodiment, the semiconductor structure 10 is formed on the upper surface of the patterned substrate, and a buffer layer 23 may further be formed between the patterned substrate and the semiconductor structure 10 to reduce the quantity of dislocations. The pattern structure of the patterned substrate can reduce the quantity of dislocations in the semiconductor structure 10 and improve the crystal quality of the semiconductor structure 10.

Optionally, the light-emitting diode 20 is a formal or flip-chip light-emitting diode driven by a small current density, such as less than 20A/cm². The light-emitting diode 20 is a small-sized chip, in which the size of at least one single side (for example, side length) is less than 300 μm. The light-emitting diode 20 may use RGB direct display screen light source or backlight display light source.

### Embodiment 2

The embodiment provides a light-emitting element. The difference between the light-emitting element of the embodiment and the light-emitting element in Embodiment 1 is as follows.

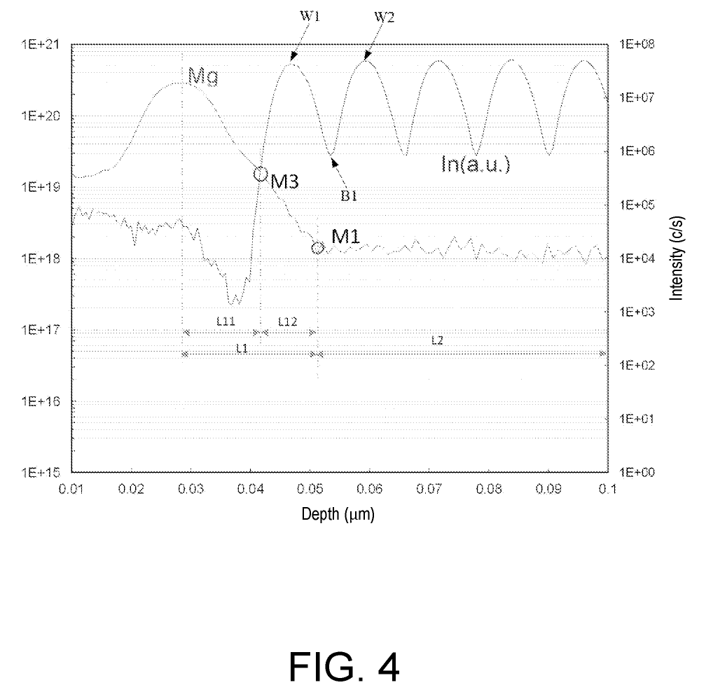

As shown in FIG. 4, in the embodiment, the sudden drop region L1 has a first sudden drop region L11 and a second sudden drop region L12. The first sudden drop region L11 is formed in the electron blocking layer 14. In the first sudden drop region L11, the concentration of Mg atoms is in a range of 1×10¹⁹ atom/cm³ to 5×10²⁰ atom/cm³. The second sudden drop region L12 is formed in the active layer, that is, within a depth range of M3 to M1 in FIG. 4. In the second sudden drop region L12, the concentration of Mg atoms is in a range of 1×10¹⁸ atom/cm³ to 2×10¹⁹ atom/cm³. Dividing the sudden drop region L1 into the first sudden drop region L11 and the second sudden drop region L12 is beneficial to controlling the depth of Mg atoms in the active layer 13, that is, it is beneficial to control the starting position of the slow drop region L2 of Mg atoms so that the position does not exceed two quantum wells. For example, in the embodiment, a starting position M1 of the slow drop region of Mg atoms is located behind a last quantum well W1 and within a barrier layer B1 in contact with the last quantum well W1 (that is, between the last quantum well W1 and a second-to-last quantum well W2 shown in FIG. 4).

By controlling the diffusion depth and the concentration change in diffusion of Mg atoms in the quantum well, the efficiency of electron-hole recombination in the active layer can be improved, the internal quantum efficiency of the epitaxial layer is improved, and the high luminous efficiency of the light-emitting diode is achieved.

### Embodiment 3

The embodiment provides a light-emitting element. In the embodiment, in the semiconductor structure of the light-emitting element, Mg atoms are also diffused to form the sudden drop region L1 and the slow drop region L2. The difference from the light-emitting element in Embodiment 1 and Embodiment 2 is as follows.

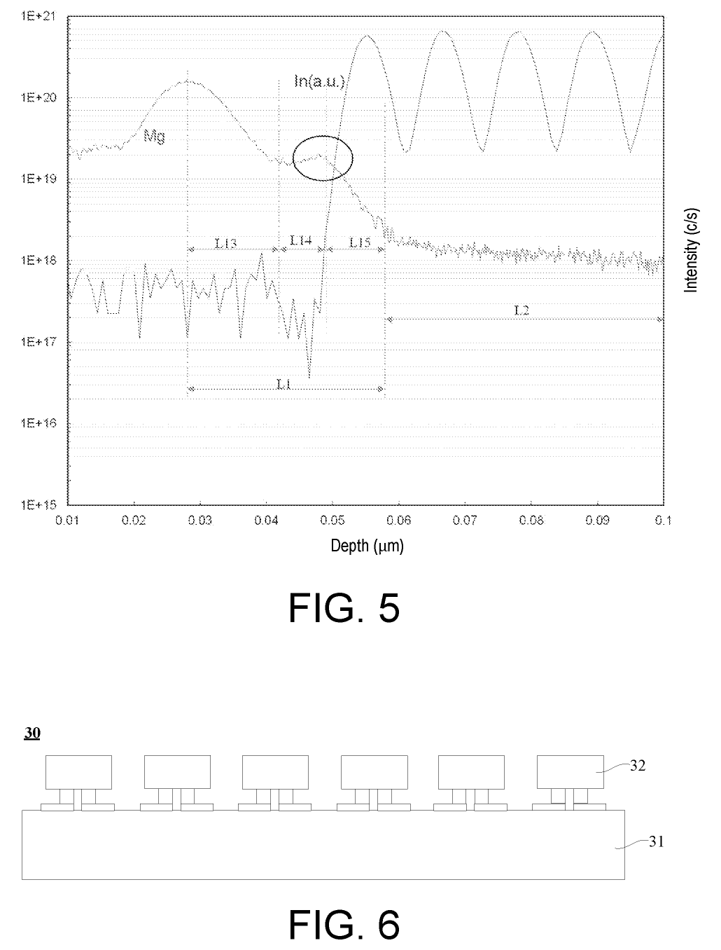

As shown in FIG. 5, in the embodiment, the sudden drop region L1 of Mg atoms is formed into a first sudden drop region L13, a buffer region L14, and a second sudden drop region L15. The first sudden drop region L13 is formed in a range of 30 nm to 40 nm from the surface of the active layer 13 in the active layer 13, the buffer region L14 is formed in a range of 40 nm to 50 nm from the surface of the active layer 13 in the active layer 13, and the second sudden drop region L15 is formed in a range of 50 nm to 60 nm from the surface of the active layer 13 in the active layer 13. The slow drop region L2 is formed in a range of being greater than 60 nm from the surface of the active layer 13. Controlling the formation depth of the sudden drop region L1 is beneficial to controlling the formation depth of the slow drop region so that the slow drop region starts after the first quantum well, thereby the impact of Mg atoms on the active layer 13 is reduced.

As shown in FIG. 5, in the first sudden drop region L13, the concentration of Mg atoms is in a range of 2×10¹⁹ atom/cm³ to 5×10²⁰ atom/cm³, in the buffer region L14, the concentration of Mg atoms is in a range of 1×10¹⁹ atom/cm³ to 2×10¹⁹ atom/cm³, and in the second sudden drop region L15, the concentration of Mg atoms is in a range of 1×10¹⁸ atom/cm³ to 2×10¹⁹ atom/cm³. That is, during the sudden decrease in the concentration of Mg atoms, the concentration of Mg atoms increases slightly in the buffer region L14, and the concentration of Mg atoms tends to be flat in the buffer region L14. Afterward, the second sudden drop region L15 is entered, and the concentration of Mg atoms continues to drop. The formation of the buffer region L14 is beneficial to well controlling the concentration of Mg atoms in the active layer 13, so that at the end of the sudden drop region L1, the concentration of Mg atoms is close to 1×10¹⁸ atom/cm³. In the subsequent slow drop region, the concentration of Mg atoms slowly decreases until the concentration is less than 5×10¹⁶ atom/cm³. In this way, in the superlattice structure layer, the concentration of Mg atoms is less than 5×10¹⁶ atom/cm³ until the concentration is negligible.

With the above diffusion characteristics of Mg atoms in the active layer, the impact of Mg atoms on MQW can be effectively reduced, the quality of MQW is improved, thereby the efficiency of electron-hole recombination in the active layer is improved, the internal quantum efficiency of the epitaxial layer is improved, and the high luminous efficiency of the light-emitting diode is achieved.

### Embodiment 4

The embodiment also provides a light-emitting element. In the semiconductor structure of the light-emitting element, Mg atoms are also diffused to form the sudden drop region L1 and the slow drop region L2. The difference from the light-emitting element in Embodiment 1 to Embodiment 3 is as follows.

As shown in FIG. 3, in the embodiment, the first superlattice layer 121 is a multi-layer structure that at least includes gallium nitride, for example, a superlattice structure 1212 that at least includes a certain thickness and contains In. Preferably, the first superlattice layer 121 at least includes a GaN layer and an InGaN layer, and may be a combination of the GaN layer and the InGaN layer. While the superlattice structure 1212 improves the crystal quality of the active layer 13, it is also achieved that the dislocation defects in the gallium nitride layer are gradually opened to form the V-surface pits 130.

As shown in FIG. 3, in this embodiment, in order to reduce the leakage channel, increase the radiation recombination ratio under small current density, and improve the luminous efficiency, the composition of the first superlattice layer 121, the distance to be close to the active layer 13, and the thickness of the first superlattice layer 121 may be controlled, which is beneficial to controlling the V-surface pits 130 so that the tips of most or all of the V-surface pits 130 are not lower than the bottom surface of the first layer of quantum well 1310 of the active layer 13, or even higher than the bottom surface of the first layer of quantum well 1310.

In an optional embodiment, the distance between the bottom surface of the first superlattice layer 121 and the bottom surface of the superlattice structure 1212 is controlled to be no more than 0.15 μm, and the distance between the bottom surface of the superlattice structure 1212 and the bottom surface of the active layer 13 is in a range of 0.05 μm to 0.3 μm. The C (carbon) doping concentration of the first superlattice layer 121 is greater than or equal to 2×10¹⁶ Atoms/cm³ and less than or equal to 5×10¹⁷Atoms/cm³, and the C doping concentration of the first superlattice layer 121 is greater than the C doping concentration of the first semiconductor layer 11. More preferably, the C doping concentration of the first superlattice layer 121 is greater than or equal to 2×10¹⁶ Atoms/cm³ and less than or equal to 8×10¹⁶ Atoms/cm3, or greater than or equal to 3×10¹⁶ Atoms/cm³ and less than or equal 8×10¹⁶ Atoms/cm³, or greater than or equal to 3×10¹⁶ Atoms/cm³ and less than or equal to 5×10¹⁶ Atoms/cm³.

As mentioned above, the first superlattice layer 121 is located above the first semiconductor layer 11 and has a low C doping concentration, thereby being able to induce surface defects of the first semiconductor layer 11 (N-type GaN layer) to open as V-pit defects at a low speed, and thus the V-surface pits 130 are opened and evenly distributed in the active layer 13.

Optionally, as shown in FIG. 3, the first superlattice layer 121 further includes a first layer structure 1211 located on the current expansion layer 112 and below the superlattice structure 1212. The bottom surface of the first layer structure 1211 is the bottom surface of the first superlattice layer 121. Also, the first layer structure 1211 is an InGaN layer or a GaN layer with a lower In content than each indium-containing layer in the superlattice structure 1212.

Preferably, the first layer structure 1211 is an N-type doped, for example, Si-doped GaN layer. The Si doping concentration of the first layer structure 1211 is in a range of 2×10¹⁸ atoms/cm³ to 1×10¹⁹ atoms/cm³, and more preferably in a range of 4×10¹⁸ atoms/cm³ to 7×10¹⁸atoms/cm³. The first layer structure 1211 has a high Si doping concentration, and the Si doping concentration is greater than the Si doping concentration of the current expansion layer 112. The first layer structure 1211 also has the function of the first superlattice layer 121 and has a high Si doping, which can prevent electrostatic damage, adjust the ESD capability of the light-emitting element, and ensure the high reliability of the light-emitting element when applied in equipment of backlight and display fields.

Preferably, the current expansion layer 112 has a thickness greater than the thickness of the first layer structure 1211 and has a lower Si doping concentration than the first layer structure 1211, that is, the thickness of the current expansion layer 112 exceeds the distance between the bottom surface of the first superlattice layer 121 and the bottom surface of the second superlattice layer 122. Thus, the current expansion effect of the current expansion layer 112 is achieved.

Also as shown in FIG. 3, optionally, the first superlattice layer 121 may further include a second layer structure 1213. The second layer structure 1213 is located on the superlattice structure 1212 and below the active layer 13, the second layer structure 1213 is a highly Si doped layer, which is located on the upper and lower sides of the superlattice structure 1212 respectively with the first layer structure 1211, thereby a synergistic function is achieved, electrostatic damage is prevented, the ESD capability of the light-emitting element is adjusted, and the high reliability of the light-emitting element when applied in backlight and display fields is ensured.

As shown in FIG. 3, the second superlattice layer 122 is formed on the first superlattice layer 121, and the second superlattice layer 122 is an InₘGa₁₋ₘN/InₙGa₁₋ₙN layer. The second superlattice layer 122 is located on the second layer structure 1213 and below the active layer 13, the second superlattice layer 122 synergizes with the superlattice structure 1212 in the first superlattice layer 121 to release the stress generated by the InGaN material layer included in the active layer 13 growing above the GaN layer when the N-type electron injection layer 111 is the GaN layer, and thus the crystal growth quality is improved and the luminous brightness of the nitride light-emitting diode is increased.

Preferably, the C doping concentration of the second superlattice layer 122 is equal to or less than the C doping concentration of the first superlattice layer 121. As an example, the C doping concentration of the second superlattice layer 122 is less than the C doping concentration of the superlattice structure 1212. The C doping concentration of the second superlattice layer 122 is less than 2×10¹⁶ atom/cm³.

Preferably, the In content of the InₘGa₁₋ₘN layer 1221 in the second superlattice layer 122 is greater than or equal to the In content of the InₓGa₁₋ₓN layer of the superlattice structure 1212. In this embodiment, the In content of the InₘGa₁₋ₘN layer 1222 in the second superlattice layer 122 is greater than the In content of the InₓGa₁₋ₓN layer of the superlattice structure 1212. Preferably, the second superlattice layer 122 has a small thickness, and the total thickness of the superlattice structure 1212 is greater than the total thickness of the second superlattice layer 122. In this way, it is realized that the first superlattice layer 121 and the active layer 13 have a close distance, most of the V-surface pits 130 are controlled to be opened in the active layer 13, at least the bottom surface tips of most of the V pits are located in the active layer 13, and the second superlattice layer 122 plays the role of releasing the stress of the active layer 13.

The first superlattice layer 121 includes a superlattice structure 1212 containing In. The incorporation of In effectively alleviates and releases the stress during the growth process of the semiconductor structure 10 and can also induce the V-surface pits 130 to gradually open in subsequent growth layers, and the second superlattice layer 122 synergizes with the superlattice structure 1212.

As mentioned above, in the embodiment, by controlling features such as the composition and thickness of the first superlattice layer 121 and the second superlattice layer 122, the opening of the V-surface pits 130 is induced and controlled so that the tips of most or all of the V-surface pits 130 are not lower than the bottom surface of the first layer of quantum well 1310 of the active layer 13, or even higher than the bottom surface of the first layer of quantum well 1310, thereby the leakage channel in the semiconductor structure is reduced, the radiation recombination ratio under small current density is increased, and the luminous efficiency is improved.

### Embodiment 5

The embodiment provides a light-emitting device. As shown in FIG. 6, a light-emitting device 30 includes a circuit substrate 31 and a light-emitting element 32 disposed on the circuit substrate 31, in which the light-emitting element 32 may be one or more of the light-emitting diodes 20 according to Embodiment 1 to Embodiment 3 of the disclosure. The light-emitting device 30 is an LED backlight device or an RGB display screen device.

The above embodiments merely illustrate the principles and effects of the disclosure, but are not intended to limit the disclosure. Persons familiar with this technology can modify or change the above embodiments without departing from the spirit and scope of the disclosure. Therefore, all equivalent modifications or changes made by persons with ordinary knowledge in the technical field without departing from the spirit and technical ideas disclosed in the disclosure shall still be covered by the claims of the disclosure.

What is claimed is:

1. A light-emitting element comprising a semiconductor structure, wherein the semiconductor structure includes a first semiconductor layer, a superlattice structure, an active layer, and a second semiconductor layer, the active layer is a multiple quantum well structure, the second semiconductor layer is a P-type doped layer and has a P-type dopant, wherein the P-type dopant diffuses to the active layer from the second semiconductor layer and forms a sudden drop region and a slow drop region, and a depth of the P-type dopant diffused from the active layer is not greater than 500 nm, wherein a concentration of the P-type dopant drops from the active layer to the superlattice structure, and a concentration of the P-type dopant within at least a portion of the superlattice structure is less than 5×10¹⁶ atom/cm³.

2. The light-emitting element as claimed in claim 1, wherein in the active layer, a concentration of the P-type dopant is in a range of 1×10¹⁷atom/cm³ to 5×10¹⁹ atom/cm³.

3. The light-emitting element as claimed in claim 1, wherein the semiconductor structure further includes an electron blocking layer formed between the active layer and the second semiconductor layer, and the P-type dopant has a peak concentration in the electron blocking layer.

4. The light-emitting element as claimed in claim 2, wherein in the sudden drop region, a diffusion depth of the P-type dopant does not exceed two quantum wells, and a concentration of the P-type dopant is in a range of 1×10¹⁸ atom/cm³ to 5×10²⁰ atom/cm³.

5. The light-emitting element as claimed in claim 3, whereinthe sudden drop region has a first sudden drop region and a second sudden drop region, the first sudden drop region is formed in the electron blocking layer, the second sudden drop region is formed in the active layer, in the first sudden drop region, a concentration of the P-type dopant is in a range of 1×10¹⁹ atom/cm³ to 5×10²⁰ atom/cm³ and in the second sudden drop region, a concentration of the P-type dopant is in a range of 1×10¹⁸ atom/cm³ to 2×10¹⁹ atom/cm³.

6. The light-emitting element as claimed in claim 4, wherein in the active layer, a quantity of pairs of quantum well and barrier layer is 3 to 15 pairs, and a quantity of pairs of material layer whose concentration of the P-type dopant being greater than 2×10¹⁸ atom/cm³ is less than or equal to 2.

7. The light-emitting element as claimed in claim 1, wherein the slow drop region is formed subsequent to the sudden drop region in the active layer, and in the slow drop region, a concentration of the P-type dopant is in a range of 2×10¹⁶ atom/cm³ to 2×10¹⁸ atom/cm³.

8. The light-emitting element as claimed in claim 3, wherein the sudden drop region has a first sudden drop region, a buffer region, and a second sudden drop region, the first sudden drop region, the buffer region, and the second sudden drop region are formed in the active layer.

9. The light-emitting element as claimed in claim 8, wherein in the first sudden drop region, a concentration of the P-type dopant is in a range of 2×10¹⁹ atom/cm³ to 5×10²⁰ atom/cm³ in the buffer region, a concentration of the P-type dopant is in a range of 1×10¹⁹ atom/cm³ to 2×10¹⁹ atom/cm³ and in the second sudden drop region, a concentration of the P-type dopant is in a range of 1×10¹⁸ atom/cm³ to 2×10¹⁹ atom/cm³.

10. The light-emitting element as claimed in claim 8, wherein in the second sudden drop region, a diffusion depth of the P-type dopant does not exceed two quantum wells.

11. The light-emitting element as claimed in claim 1, wherein in a stacking direction of the semiconductor structure, a first pair of quantum well and barrier layer of the active layer are adjacent to the first semiconductor layer, a last pair of barrier layer and quantum well of the active layer are adjacent to the second semiconductor layer, and in the quantum well of the first pair, a concentration of the P-type dopant is greater than 5×10¹⁶ atom/cm³ and less than 1×10¹⁷ atom/cm³.

12. The light-emitting element as claimed in claim 11, wherein in the quantum well of the last pair, a concentration of the P-type dopant is greater than 1×10¹⁸ atom/cm³ and less than 1×10¹⁹ atom/cm³.

13. The light-emitting element as claimed in claim 11, wherein a second-to-last pair of quantum well and barrier layer of the active layer is adjacent to the last pair of quantum well and barrier layer, and in the quantum well of the second-to-last pair, a concentration of the P-type dopant is greater than 1×10¹⁸ atom/cm³ and less than 2×10¹⁸ atom/cm³.

14. The light-emitting element as claimed in claim 11, wherein the quantum well in the active layer is an indium-containing layer.

15. The light-emitting element as claimed in claim 1, wherein in the superlattice structure layer, a concentration of the P-type dopant is less than 5×10¹⁶ atom/cm³.

16. The light-emitting element as claimed in claim 1, wherein the P-type dopant is a magnesium atom.

17. A light-emitting device comprising a circuit substrate and a light-emitting element disposed on the circuit substrate, wherein the light-emitting element comprises the light-emitting element as claimed in claim 1.

18. A light-emitting device comprising a circuit substrate and a light-emitting element disposed on the circuit substrate, wherein the light-emitting element comprises the light-emitting element as claimed in claim 2.

19. A light-emitting device comprising a circuit substrate and a light-emitting element disposed on the circuit substrate, wherein the light-emitting element comprises the light-emitting element as claimed in claim 3.

20. A light-emitting device comprising a circuit substrate and a light-emitting element disposed on the circuit substrate, wherein the light-emitting element comprises the light-emitting element as claimed in claim 4.
